(19) United States
(12) Patent Application Publication
(10) Pub. No.: US 2026/0135069 A1
(43) Pub. Date: May 14, 2026

(54) PLASMA VACUUM CHAMBER

(71) Applicant: Shanghai Huali Integrated Circuit Corporation, Shanghai (CN)

(72) Inventors: Yukun LV, Shanghai (CN); Zaifeng TANG, Shanghai (CN); Jin XU, Shanghai (CN); Penghua YUAN, Shanghai (CN)

(73) Assignee: Shanghai Huali Integrated Circuit Corporation, Shanghai (CN)

(21) Appl. No.: 19/220,984

(22) Filed: May 28, 2025

(30) Foreign Application Priority Data
Nov. 13, 2024 (CN) 202411622788.X

(51) Int. Cl. H01J 37/32; H01J 37/18; H01L 21/683

(52) U.S. Cl. CPC H01J 37/32715; H01J 37/18; H01J 37/32183; H10P 72/722; H01J 2237/3343

(57) ABSTRACT

Disclosed is a plasma vacuum chamber, including: a chamber body; and an electrostatic chuck rotatably provided on a side wall of the chamber body. The electrostatic chuck includes a first surface for placing a wafer. The electrostatic chuck is rotatable at an angle of at least 180°, and the electrostatic chuck has a first rotation position state and a second rotation position state. In the first rotation position state, the first surface faces upward, and a space for picking up and placing the wafer is provided above the first surface to pick and place the wafer from and on the first surface. In the second rotation position state, the first surface faces downward, and a plasma formation space is provided below the first surface, the plasma formation space being used for forming plasma and performing a plasma process on the wafer electrostatically adsorbed on the first surface.

### CROSS-REFERENCES TO RELATED APPLICATIONS

This application claims priority to Chinese patent application No. CN202411622788.X, filed on Nov. 13, 2024, the disclosure of which is incorporated herein by reference in its entirety.

### TECHNICAL FIELD

The present disclosure relates to a semiconductor integrated circuit manufacturing device, and in particular, to a plasma vacuum chamber.

### BACKGROUND

With the development of integrated circuits, a plasma etching process is widely used in semiconductor manufacturing. Plasma is generally produced by exciting a reaction gas with a radio frequency in a vacuum reaction chamber. Designs of the reaction chamber currently are classified into a parallel capacitor plate type, an inductor type, a dual radio frequency capacitor type, a microwave type, and the like.

Generally, a silicon wafer is transferred by a manipulator arm to a silicon wafer carrier in an etching reaction chamber in a vacuum state for a process. Since a front side of the silicon wafer faces upward, a particle in the chamber tends to fall on the surface of the silicon wafer due to the gravity. If the particle falls down before or during etching, a total or partial etch block defect occurs; and if the particle falls down after etching, a floating particle defect occurs, thereby affecting the wafer yield. To avoid such a situation, many measures are adopted in the use and design of a device, such as an automatic pressure control (APC) valve hold (hold) function, and a continuous plasma function. However, as the process advances, a line width becomes increasingly small, and therefore the requirement for the particle becomes increasingly high.

Forces applied to the particle in the chamber include gravity, a neutral particle drag force, an ion drag force, and an electric field force. An expression for the gravity on the particle is very simple, i.e., a product of the mass of the particle and the gravitational acceleration:

$$Fg = 4 / 3 * π a 3 {ρ}_{m d} g ; \qquad ( 1 )$$

In formula (1), ρ_{md} is the mass density of a dust particle, and g=9.8 m/s² is the gravitational acceleration.

FIG. 1 is a schematic structural diagram of a plasma vacuum chamber of an existing dry etching machine. The plasma vacuum chamber of an existing dry etching machine includes: a chamber body 101.

An electrostatic chuck 102 is provided in the chamber body 101, where the electrostatic chuck 102 is a fixed structure with a top surface facing upward.

During the process, a wafer 103 is placed on the top surface of the electrostatic chuck 102 and fixed through electrostatic adsorption.

A gas inlet 104 and an inductor coil 105 are both provided on a top plate of the chamber body 101. A gas is introduced from the gas inlet 104 at the top, and the inductor coil 105 generates a varying electromagnetic field under the action of a radio frequency signal corresponding to a source power supply, where the varying electromagnetic field acts on gas molecules inside the chamber body 101 to produce plasma.

The chamber body 101 is vacuumized before the wafer 103 enters the chamber body.

A vacuumizing system includes two stages of vacuum pumps, which are a dry pump 108 and a turbo pump 107 respectively.

The dry pump 108 performs vacuumizing first to realize rough vacuumizing, i.e., vacuumizing reaching a degree. The turbo pump 107 starts vacuumizing only after the rough vacuumizing reaches a degree, so as to realize fine vacuumizing, i.e., vacuumizing reaching a value required by the process.

Referring to FIG. 1, during the rough vacuumizing, a throttle gate valve (TGV) 106 is closed, an isolation valve 111 is closed, and an isolation valve 110 is opened. In this way, during the rough vacuumizing, an internal region of the chamber body 101 is in no communication with the turbo pump 107, so that a high pressure inside the chamber body 101 does not affect a blade of the turbo pump 107, thus protecting the turbo pump 107. In this case, as the isolation valve 110 is opened, the chamber body 101 is connected to the dry pump 108 and realizes rough vacuumizing of the chamber body 101 through vacuum lines 109, i.e., a foreline, of a branch where the isolation valve 110 is located.

When the internal pressure in the chamber body 101 is reduced as not affecting the turbo pump 107, the isolation valve 110 is closed, the isolation valve 111 is opened, and the throttle gate valve 106 is opened, so as to realize fine vacuumizing of the chamber body 101, continuing to reduce the pressure in the chamber body 101. An angle of the blade of the throttle gate valve 106 is adjustable, making it possible to adjust a force of vacuumizing the chamber body 101 and thus adjust the pressure in the chamber body 101.

In FIG. 1, in the normal process, the isolation valve 110 is kept in a normally closed state, and the isolation valve 111 kept in a normally opened state. The state shown in FIG. 1 is a state in which the isolation valve 110 is closed and the isolation valve 111 is opened, in which case the branch where the isolation valve 110 is located is closed. A gas pumping direction as is shown by the arrow line 114, which sequentially passes through the turbo pump 107, the downstream vacuum lines 109, and the dry pump 108.

In the normal process, a process gas flows into the chamber body 101 from the gas inlet 104, where a corresponding inlet gas flow is as shown by the arrow line 112.

At the bottom of the chamber body 101, a reacted gas is pumped by the vacuumizing system, where a corresponding pumped gas flow is as shown by the arrow line 113.

However, as the process proceeds, by-products accumulate inside the chamber body 101 or in the vacuum lines 109, and in particular, by-products accumulate in the vacuum lines 109 between the turbo pump 107 and the dry pump 108, i.e., particles 115 accumulate.

During the process, the particles 115 may rise to the top of the wafer 103 with a reverse gas flow 116, in which case the particles 115 fall on the top surface of the wafer 103 under the action of the gravity, resulting in a corresponding defect. Taking a plasma etching process as an example, if the particles 115 fall on the surface of the wafer 103 before the plasma etching process is completed, etching cannot be continued in a region covered by the particles 115 as the particles 115 blocks the etching of a material of the region covered by the particles 115. If the particles 115 fall down after the plasma etching process is completed, the etching causes a particle defect, which may also affect the product yield.

FIG. 2 is a defect map 201 after plasma etching in the plasma vacuum chamber of the existing dry etching machine shown in FIG. 1. Coordinates of the map 201 are in one-to-one correspondence with coordinates of an actual wafer, and the position of a defect on the map 201 is in one-to-one correspondence with the position of an actual defect on the wafer. It can be seen that a plurality of defects 202 are present on the wafer.

FIG. 3 is an enlarged photograph of a defect in FIG. 2. In FIG. 3, a pattern 203 is an etched pattern. It can be seen that no pattern 203 is formed in a region covered by the defect 202, finally affecting the product yield.

### BRIEF SUMMARY

According to some embodiments in this application, a plasma vacuum chamber disclosed in this application comprising: a chamber body; and an electrostatic chuck rotatably provided on a side wall of the chamber body, where
the electrostatic chuck includes a first surface for placing a wafer;
the electrostatic chuck is rotatable at an angle of at least 180°, and the electrostatic chuck has a first rotation position state and a second rotation position state;
in the first rotation position state, the first surface faces upward, and a space for picking up and placing the wafer is provided above the first surface to pick and place the wafer from and on the first surface; and
in the second rotation position state, the first surface faces downward, and a plasma formation space is provided below the first surface, the plasma formation space being used for forming plasma and performing a plasma process on the wafer electrostatically adsorbed on the first surface.

In some cases, the electrostatic chuck includes an electrostatic chuck body and a cantilever.

A first hole passing through the side wall is provided on the side wall of the chamber body where the electrostatic chuck is provided, the cantilever passes through the first hole, and a gap between the cantilever and an inner surface of the first hole is sealed by a seal ring.

The cantilever is connected to a rotary actuator outside the chamber body, and the rotary actuator drives the cantilever to rotate and thereby drives the electrostatic chuck to rotate, so as to switch the electrostatic chuck between the first rotation position state and the second rotation position state.

In some cases, a wafer inlet-outlet port and a corresponding door plate are formed on a side wall of the chamber body on the periphery of the space for picking up and placing the wafer.

The door plate is used to close and open the wafer inlet-outlet port.

In some cases, a material of the seal ring includes a magnetic fluid.

In some cases, a first energy source supply apparatus is provided on a side wall or bottom plate of the chamber body at the bottom of the electrostatic chuck to supply a first energy source to the plasma.

In some cases, the first energy source supply apparatus includes a first inductor coil, the first inductor coil being wound around the side wall or bottom plate of the chamber body at the bottom of the electrostatic chuck.

The first inductor coil is connected to a source power supply.

In some cases, the first inductor coil is of a planar structure and provided on the bottom plate of the chamber body at the bottom of the electrostatic chuck.

In some cases, a gas inlet is also provided on the bottom plate of the chamber body, an external port of the gas inlet is connected to a corresponding gas supply line, and an internal port of the gas inlet is located inside the chamber body.

In some cases, a exhaust port is provided on the side wall of the chamber body at the bottom of the electrostatic chuck, the exhaust port being connected to a vacuumizing system.

In some cases, the source power supply is provided by a first radio frequency generator, and a first match circuit is connected between the first radio frequency generator and the first inductor coil.

In some cases, the electrostatic chuck is connected to a bias power supply.

In some cases, the bias power supply is provided by a second radio frequency generator, and a second match circuit is connected between the second radio frequency generator and the electrostatic chuck.

In some cases, structures connected to the electrostatic chuck further include: a chiller, a helium control system, and a chucking system.

In some cases, the vacuumizing system includes a plurality of stages of vacuum pumps, valves, and vacuum lines.

In some cases, multiple lift pins are also provided in the electrostatic chuck.

In some cases, the chamber body is an etching chamber body.

Unlike the prior art in which the electrostatic chuck is a fixed structure, the present disclosure provides the electrostatic chuck as being a rotatable structure, and the electrostatic chuck is used for picking up and placing the wafer in the first rotation position state where the first surface faces upward and for performing the plasma process in the second rotation position state where the first surface faces downward. In this way, in the plasma process, since the first surface faces downward, particles cannot fall on the surface of the wafer under the action of gravity. Therefore, the present disclosure can fully avoid an impact of the gravity on dust particles during the process, fully prevent the particles from falling on the surface of the wafer due to the gravity which leads to surface contamination of a wafer product, and finally can increase process selection solutions and process formulation windows.

Since the present disclosure eliminates the particles falling on the surface of the wafer due to the gravity, the present disclosure can effectively reduce the number of particles falling on the surface of the wafer. When the plasma process is an etching process, as particles on the surface of the wafer have been effectively reduced, the number of defects formed by particles blocking the etching is also effectively reduced. Therefore, the present disclosure can effectively reduce the defects on the surface of the wafer formed by the particles blocking the etching during the process, finally extend a period of maintaining the chamber body, and increase the utilization rate of the machine.

### BRIEF DESCRIPTION OF THE DRAWINGS

The present disclosure is further described in detail below with reference to the accompanying drawings and specific embodiments:

FIG. 1 is a schematic structural diagram of a plasma vacuum chamber of an existing dry etching machine;

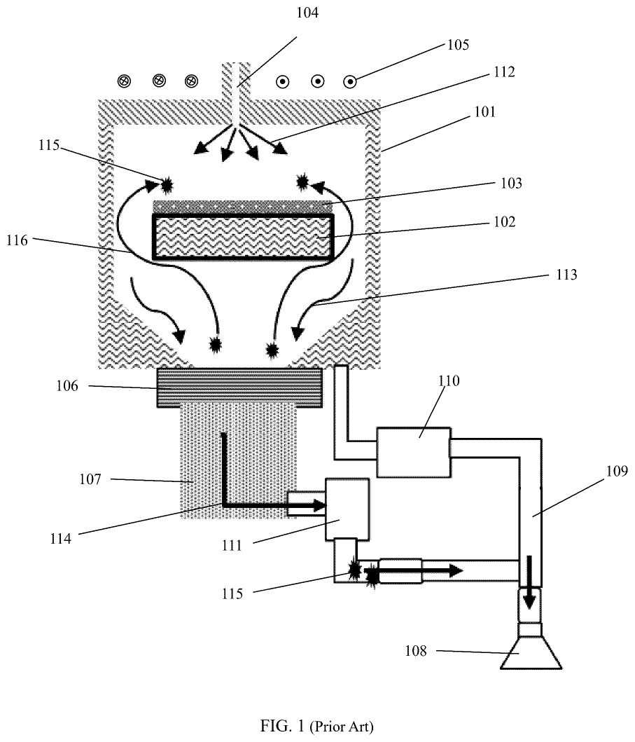

FIG. 2 is a defect map after plasma etching in the plasma vacuum chamber of the existing dry etching machine shown in FIG. 1;

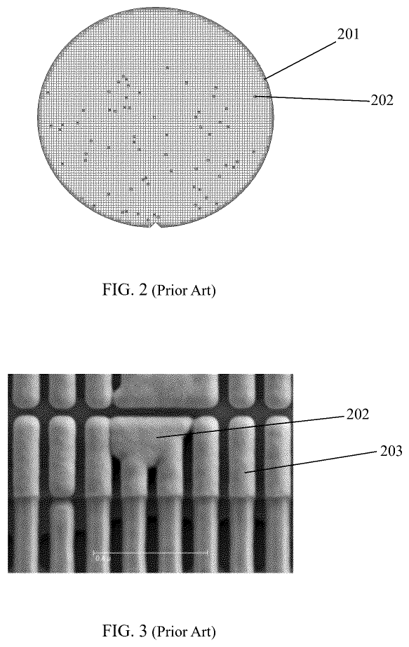

FIG. 3 is an enlarged picture of a defect in FIG. 2;

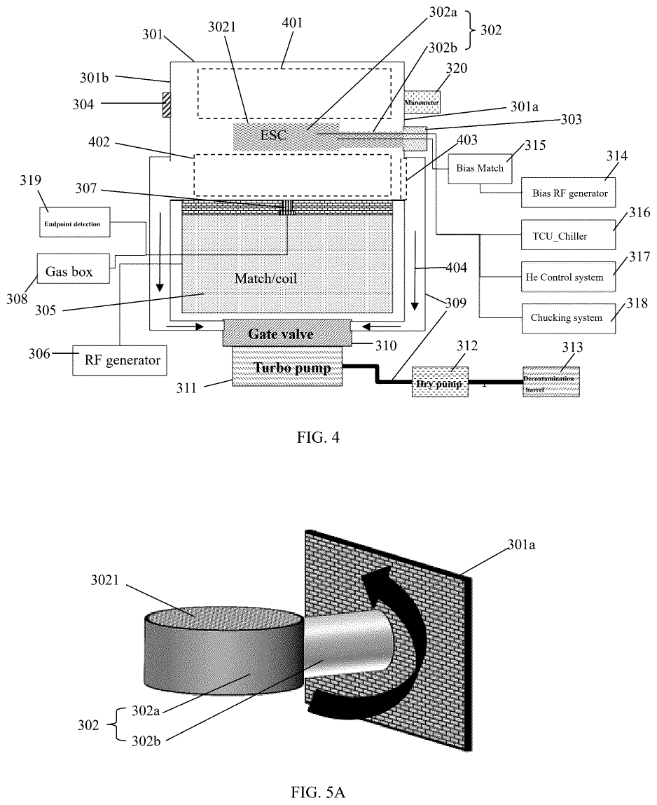

FIG. 4 is a schematic structural diagram of a plasma vacuum chamber according to an embodiment of the present disclosure;

FIG. 5A is a stereoscopic enlarged view of an electrostatic chuck of the plasma vacuum chamber according to an embodiment of the present disclosure;

FIG. 5B is a sectional view of a cantilever of the electrostatic chuck of the plasma vacuum chamber on a side wall according to an embodiment of the present disclosure; and

FIGS. 6A-6G are schematic structural diagrams of the plasma vacuum chamber in a plasma process according to an embodiment of the present disclosure.

### DETAILED DESCRIPTION OF THE DISCLOSURE

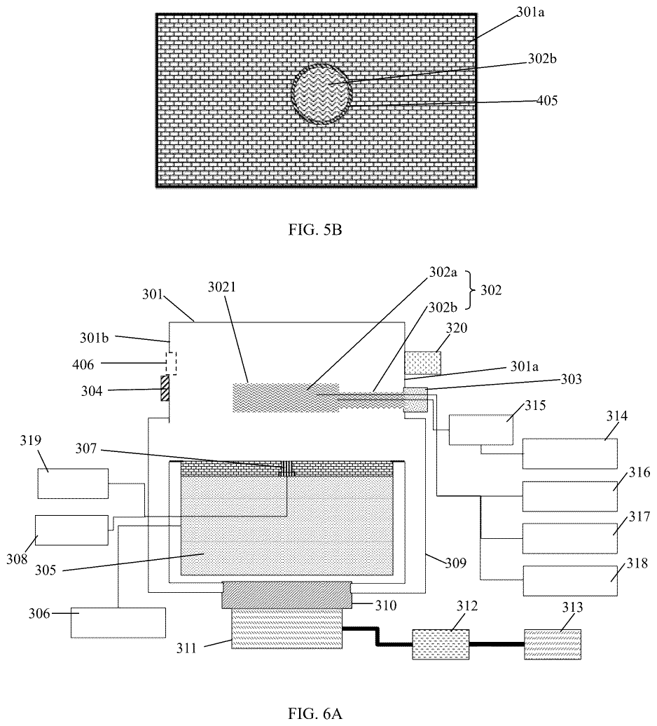

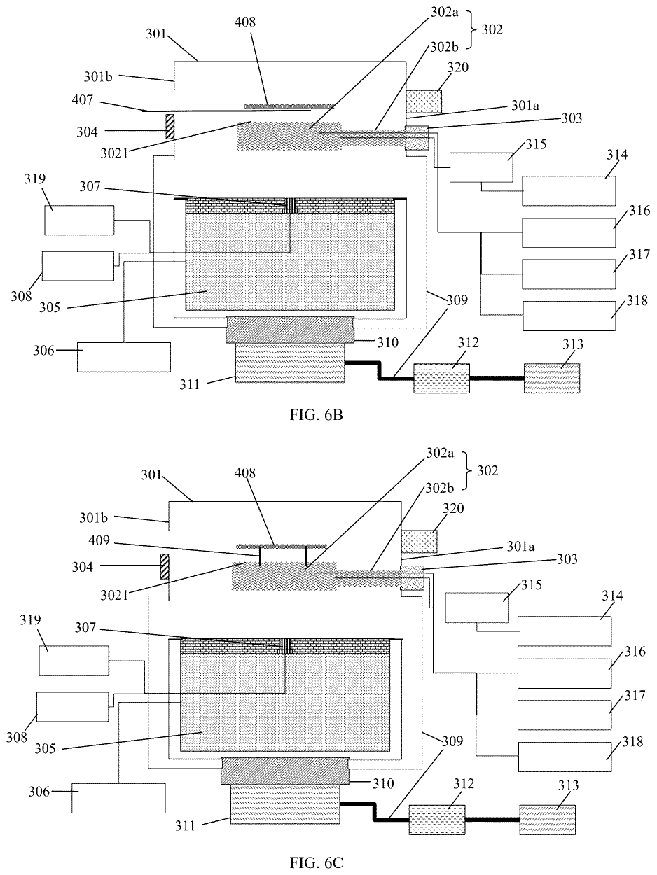

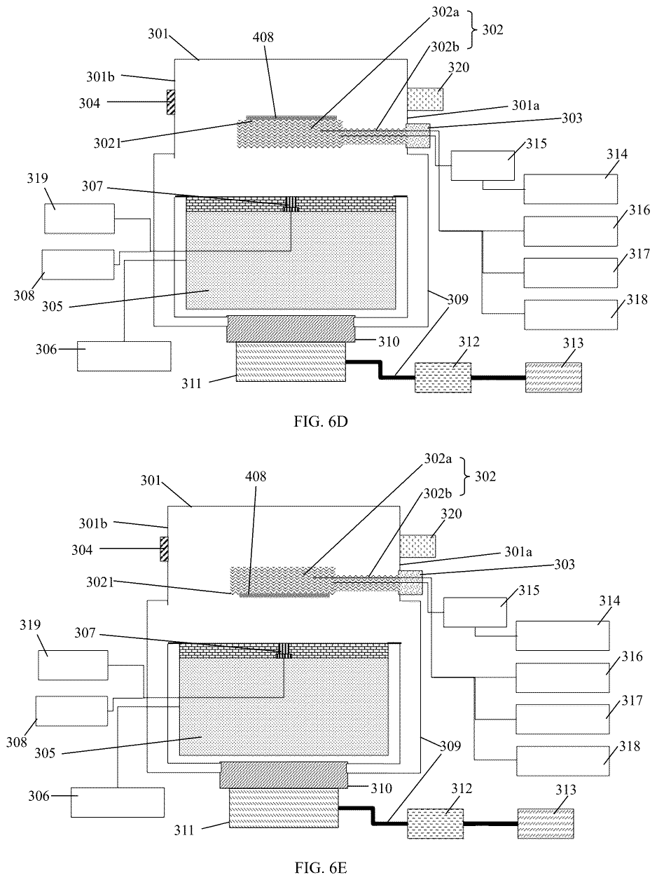

FIG. 4 is a schematic structural diagram of a plasma vacuum chamber according to an embodiment of the present disclosure. FIG. 5A is a stereoscopic enlarged view of an electrostatic chuck of the plasma vacuum chamber according to an embodiment of the present disclosure. FIG. 5B is a sectional view of a cantilever of the electrostatic chuck of the plasma vacuum chamber on a side wall according to an embodiment of the present disclosure. The plasma vacuum chamber according to this embodiment of the present disclosure includes a chamber body 301.

An electrostatic chuck (ESC) 302 is rotatably provided on a side wall of the chamber body 301. In FIG. 4, the side wall corresponding to the electrostatic chuck 302 is separately marked with a mark 301a. The electrostatic chuck 302 is also denoted by ESC.

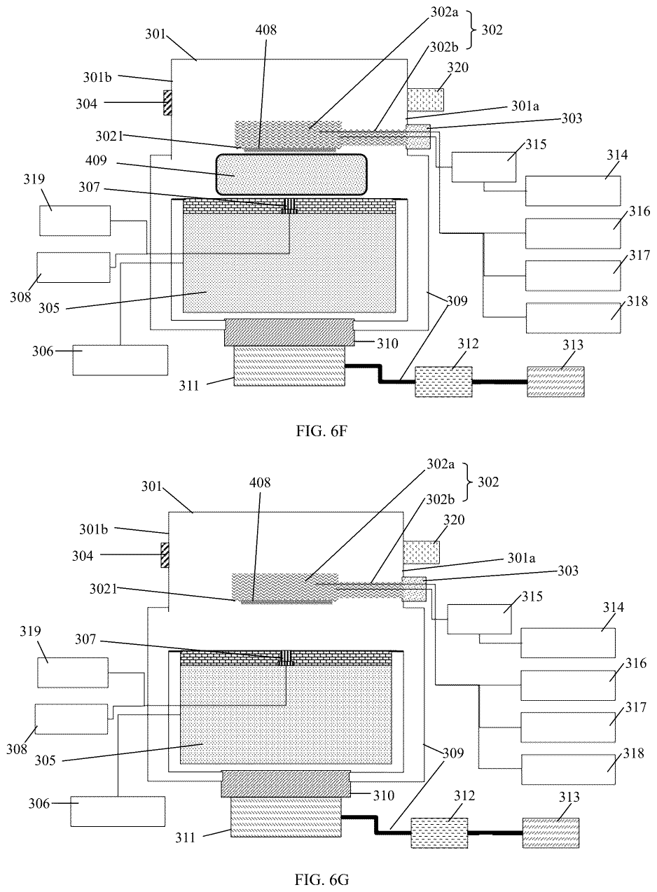

The electrostatic chuck 302 includes a first surface 3021 for placing a wafer 408. For the wafer 408, please also refer to FIG. 6D.

The electrostatic chuck 302 is rotatable at an angle of at least 180°, and the electrostatic chuck 302 has a first rotation position state and a second rotation position state.

The first rotation position state is shown in FIG. 4. In the first rotation position state, the first surface 3021 faces upward, and a space for picking up and placing the wafer 408 is provided above the first surface 3021 to pick and place the wafer 408 from and on the first surface 3021.

In the second rotation position state, the first surface 3021 faces downward, and a plasma formation space is provided below the first surface 3021, the plasma formation space being used for forming plasma and performing a plasma process on the wafer electrostatically adsorbed on the first surface 3021. For the second rotation position state, please also refer to FIG. 6E.

In this embodiment of the present disclosure, the electrostatic chuck 302 includes an electrostatic chuck body 302a and a cantilever 302b.

Referring to FIG. 5A, a first hole passing through the side wall 301a is provided on the side wall 301a of the chamber body 301 where the electrostatic chuck 302 is provided, and the cantilever 302b passes through the first hole. In FIG. 5A, the rotation arrow line indicates that the electrostatic chuck 302 is rotatable. In some preferred embodiments, the electrostatic chuck 302 is rotatable at an angle of 360°.

Referring to FIG. 5B, a gap between the cantilever 302b and an inner surface of the first hole is sealed by a seal ring 405.

In some preferred embodiments, a material of the seal ring 405 includes a magnetic fluid.

Referring to FIG. 4, the cantilever 302b is connected to a rotary actuator 303 outside the chamber body 301, and the rotary actuator 303 drives the cantilever 302b to rotate and thereby drives the electrostatic chuck 302 to rotate, so as to switch the electrostatic chuck 302 between the first rotation position state and the second rotation position state.

In this embodiment of the present disclosure, a wafer inlet-outlet port 406 and a corresponding door plate 304 are formed on a side wall of the chamber body 301 on the periphery of the space for picking up and placing the wafer 408.

The door plate 304 is used to close and open the wafer inlet-outlet port 406.

In FIG. 4, the side wall corresponding to the door plate 304 is marked with a mark 301b. For the wafer inlet-outlet port 406, please refer to FIG. 6A. FIG. 4 shows that wafer inlet-outlet port 406 in a closed state; and FIG. 6A shows the wafer inlet-outlet port 406 in an opened state.

In this embodiment of the present disclosure, a first energy source supply apparatus 305 is provided on a side wall or bottom plate of the chamber body 301 at the bottom of the electrostatic chuck 302 to supply a first energy source to the plasma. The first energy source is a varying magnetic or electric field, and the plasma is produced by the action of the first energy source on gas molecules in the chamber body 301.

In some embodiments, the first energy source supply apparatus 305 includes a first inductor coil, the first inductor coil being wound around the side wall or bottom plate of the chamber body 301 at the bottom of the electrostatic chuck 302. The plasma produced using the first energy source provided by the first inductor coil is inductively coupled plasma (ICP).

The first inductor coil is connected to a source power supply.

The source power supply is provided by a first radio frequency generator (RF generator) 306, and a first match circuit is connected between the first radio frequency generator 306 and the first inductor coil. In FIG. 4, the first energy source supply apparatus 305 is also denoted by Match/coil. The first radio frequency generator 306 is also denoted by RF generator.

In some preferred embodiments, the first inductor coil is of a planar structure and provided on the bottom plate of the chamber body 301 at the bottom of the electrostatic chuck 302. In this case, the plasma is further represented as transformer coupled plasma (TCP). In other embodiments, the first inductor coil may also be of a stereoscopic structure, in which case the first inductor coil may also be wound around the side wall of the chamber body 301 at the bottom of the electrostatic chuck 302.

A gas inlet 307 is also provided on the bottom plate of the chamber body 301. Such a feature is different from that the gas inlet is provided on a top plate of the chamber body in the prior art. An external port of the gas inlet 307 is connected to a corresponding gas supply line, and an internal port of the gas inlet 307 is located inside the chamber body 301. Generally, the gas supply line is configured according to a gas required in the process. Typically, one gas supply line is required for one type of gas. Gas supply lines for various gases are generally dispensed from a gas box 308. Generally, a manual valve, a solenoid valve, a pressure regulator, a pressure meter, a flow meter, etc. are provided in the gas box 308 to facilitate control of a gas supplied into the chamber body 301, including opening and closing, flow control, pressure regulation, etc.

In some embodiments, a pipeline of an endpoint monitoring apparatus 319 is also drawn from the bottom of the chamber body 301. The endpoint monitoring apparatus 319 includes a spectral reflectometer or an optical emission spectrometer (OES).

In this embodiment of the present disclosure, a exhaust port 403 is provided on the side wall of the chamber body 301 at the bottom of the electrostatic chuck 302, the exhaust port 403 being connected to a vacuumizing system. The feature of providing the exhaust port 403 on the side wall of the chamber body 301 in this embodiment of the present disclosure is different from a feature of providing the exhaust port on the bottom plate of the chamber body in the prior art. In this embodiment of the present disclosure, since no exhaust port is provided on the bottom plate of the chamber body 301, the first energy source supply apparatus 305 may be provided on the bottom plate of the chamber body 301. FIG. 4 shows that the exhaust port 403 is provided on both of the sidewalls 301a and 301b. The provision of the exhaust port 403 on both sides makes gas pumping more uniform, resulting in a better vacuuming effect.

In this embodiment of the present disclosure, the electrostatic chuck 302 is connected to a bias power supply.

The bias power supply is provided by a second radio frequency generator 314, and a second match circuit 315 is connected between the second radio frequency generator and the electrostatic chuck 302. In FIG. 4, the second radio frequency generator 314 is separately denoted by Bias RF generator, and the second match circuit 315 is separately denoted by Bias match. The bias power supply is used to provide bias energy for the plasma, so that ionic energy of the plasma is adjustable. The source power supply is mainly used to adjust a concentration of the plasma. When the plasma is used in the etching process, the ionic energy used for etching can be adjusted to a desired magnitude through the bias power supply.

In this embodiment of the present disclosure, structures connected to the electrostatic chuck 302 further includes: a chiller 316, a helium control system (He control system) 317, and a chucking system 318.

In some embodiments, the chiller 316 is a temperature control unit (TCU), so the chiller is also denoted by TCU_Chiller in FIG. 4. The chiller 316 is mainly used to control an overall temperature of the electrostatic chuck 302, to stabilize the overall temperature of the electrostatic chuck 302.

The helium control system 317 is also denoted by He Control system in FIG. 4, and is mainly used to take away heat from the wafer 408 and to make temperatures of various regions of the wafer 408 uniform in the plasma process such as a plasma etching process.

The chucking system 318 is also denoted by Chucking system in FIG. 4, and is used to control static electricity of the electrostatic chuck 302. The static electricity is usually provided by a direct-current power supply, and the magnitude and presence or absence of the static electricity of the electrostatic chuck 302 may be controlled by controlling the direct-current power supply.

In this embodiment of the present disclosure, the vacuumizing system includes a plurality of stages of vacuum pumps, valves, and vacuum lines.

Due to an excessively large pressure difference from an atmospheric pressure to a vacuum pressure, it is necessary to undergo various vacuum states of different magnitudes during vacuumizing. In order to realize well vacuumizing, a plurality of stages of vacuum pumps are required. In some embodiments, two stages of vacuum pumps are included. FIG. 4 shows a primary vacuum pump shown as being a dry pump 312 and a secondary vacuum pump as being a turbo pump 311.

In FIG. 4, the dry pump 312 is also denoted by Dry pump, and the turbo pump 311 is also denoted by Turbo pump.

The dry pump 312 is used for rough vacuumizing, in which case a gate valve 310 of a passage between the turbo pump 311 and the chamber body 301 is closed, a gas discharge branch (not shown) between the dry pump 312 and the chamber body 301 is opened, and the chamber body 301 is vacuumized only through the dry pump 312. When the vacuumizing reaches a vacuum degree at which the turbo pump 311 can work, the gate valve 310 is opened, and the gas discharge branch between the dry pump 312 and the chamber body 301 is closed at the same time. In this case, fine vacuumizing of the chamber body 301 is realized through the turbo pump 311 and the dry pump 312 sequentially, so that a vacuum pressure reaches a desired low value.

In the plasma process, poisonous and harmful substances, including powders, liquids, or gases, are usually generated, and a decontamination barrel 313 is generally provided at a downstream end of the dry pump 312. The decontamination barrel 313 is also denoted by Decontamination barrel in FIG. 4.

In this embodiment of the present disclosure, a manometer 320 in communication with the interior of the chamber body 301 is provided on the chamber body 301 and used to measure a value of a vacuum pressure inside the chamber body 301.

In this embodiment of the present disclosure, multiple lift pins 409 are also provided in the electrostatic chuck 302. For a structure of the lift pins 409, please refer to FIG. 6C.

In this embodiment of the present disclosure, the chamber body 301 is an etching chamber body 301.

Unlike the prior art in which the electrostatic chuck is a fixed structure, this embodiment of the present disclosure provides the electrostatic chuck 302 as being a rotatable structure, and the electrostatic chuck 302 is used for picking up and placing the wafer 408 in the first rotation position state where the first surface 3021 faces upward and for performing the plasma process in the second rotation position state where the first surface 3021 faces downward. In this way, in the plasma process, since the first surface 3021 faces downward, particles cannot fall on the surface of the wafer 408 under the action of gravity. Therefore, this embodiment of the present disclosure can fully avoid an impact of the gravity on dust particles during the process, fully prevent the particles from falling on the surface of the wafer 408 due to the gravity which leads to surface contamination of a wafer 408 product, and finally can increase process selection solutions and process formulation windows.

Since this embodiment of the present disclosure eliminates the particles falling on the surface of the wafer 408 due to the gravity, this embodiment of the present disclosure can effectively reduce the number of particles falling on the surface of the wafer 408. When the plasma process is an etching process, as particles on the surface of the wafer 408 have been effectively reduced, the number of defects formed by particles blocking the etching is also effectively reduced. Therefore, this embodiment of the present disclosure can effectively reduce the defects on the surface of the wafer 408 formed by the particles blocking the etching during the process, finally extend a period of maintaining the chamber body 301, and increase the utilization rate of the machine.

The plasma vacuum chamber of this embodiment of the present disclosure is further described below with reference to an action of the plasma vacuum chamber in the plasma process of this embodiment of the present disclosure. FIGS. 6A-6G are schematic structural diagrams of the plasma vacuum chamber in the plasma process according to this embodiment of the present disclosure. The plasma process includes the following steps.

First, placement of the wafer 408 is performed, including the following:

Referring to FIG. 6A, the electrostatic chuck 302 is in the first rotation position state where the first surface 3021 faces upward, in which case the door plate 304 is opened.

Referring to FIG. 6B, the arm 407 of the manipulator moves the wafer 408 over a desired process position.

Referring to FIG. 6C, the lift pins 409 rise to lift the wafer 408, the arm 407 is retracted at the time, and the door plate 304 is closed.

Referring to FIG. 6D, the lift pins 409 drop, the wafer 408 is placed on the first surface 3021 of the electrostatic chuck 302, then static electricity is turned on, and the wafer 408 is fixed on the first surface 3021 through the static electricity.

Then rotation of the electrostatic chuck 302 is performed, including the following:

Referring to FIG. 6E, the electrostatic chuck 302 is rotated 180° so that the electrostatic chuck 302 is in the second rotation position state where the first surface 3021 faces downward.

Then the plasma process is started, including the following:

Referring to FIG. 6F, a gas is introduced, the first radio frequency generator 306 and the second radio frequency generator 314 work, and finally the plasma 409 is formed in the plasma formation space at the bottom of the electrostatic chuck 302.

A process, such as an etching process, is performed on the surface of the wafer 408 using the plasma 409.

Then the plasma process is ended, including the following:

Referring to FIG. 6G, the first radio frequency generator 306 and the second radio frequency generator 314 stop working, the gas stops flowing in, and the plasma 409 is extinguished.

Then picking-up of the wafer 408 is performed, where the picking-up of the wafer 408 is performed in a reverse order compared with the placement and includes the following:

Referring to FIG. 6D, the electrostatic chuck 302 is rotated 180° so that the electrostatic chuck 302 is the first rotation position state where the first surface 3021 faces upward.

Referring to FIG. 6C, the lift pins 409 rise to lift the wafer 408, and the door plate 304 is opened.

Referring to FIG. 6B, the arm 407 of the manipulator extends, and the lift pins 409 are dropped, so that the wafer 408 is transferred to the arm 407.

Referring to FIG. 6A, the arm 407 is retracted to pick up the wafer 408. Then the door plate 304 is closed.

The present disclosure is described in detail above through specific embodiments, which, however, do not impose limitations to the present disclosure. Without departing from the principle of the present disclosure, a person skilled in the art may also made many other deformations and improvements, which should also be considered as the protection scope of the present disclosure.

What is claimed is:

1. A plasma vacuum chamber, comprising: a chamber body; and
an electrostatic chuck rotatably provided on a side wall of the chamber body, wherein
the electrostatic chuck comprises a first surface for placing a wafer;
the electrostatic chuck is rotatable at an angle of at least 180°, and the electrostatic chuck has a first rotation position state and a second rotation position state;
in the first rotation position state, the first surface faces upward, and a space for picking up and placing the wafer is provided above the first surface to pick and place the wafer from and on the first surface; and
in the second rotation position state, the first surface faces downward, and a plasma formation space is provided below the first surface, the plasma formation space being used for forming plasma and performing a plasma process on the wafer electrostatically adsorbed on the first surface.

2. The plasma vacuum chamber according to claim 1, wherein
the electrostatic chuck comprises an electrostatic chuck body and a cantilever;
a first hole passing through the side wall is provided on the side wall of the chamber body where the electrostatic chuck is provided, the cantilever passes through the first hole, and a gap between the cantilever and an inner surface of the first hole is sealed by a seal ring; and
the cantilever is connected to a rotary actuator outside the chamber body, and the rotary actuator drives the cantilever to rotate and thereby drives the electrostatic chuck to rotate, so as to switch the electrostatic chuck between the first rotation position state and the second rotation position state.

3. The plasma vacuum chamber according to claim 1, wherein a wafer inlet-outlet port and a corresponding door plate are formed on a side wall of the chamber body on the periphery of the space for picking up and placing the wafer; and
the door plate is used to close and open the wafer inlet-outlet port.

4. The plasma vacuum chamber according to claim 2, wherein a material of the seal ring comprises a magnetic fluid.

5. The plasma vacuum chamber according to claim 1, wherein a first energy source supply apparatus is provided on a side wall or bottom plate of the chamber body at the bottom of the electrostatic chuck to supply a first energy source to the plasma.

6. The plasma vacuum chamber according to claim 5, wherein the first energy source supply apparatus comprises a first inductor coil, the first inductor coil being wound around the side wall or bottom plate of the chamber body at the bottom of the electrostatic chuck; and
the first inductor coil is connected to a source power supply.

7. The plasma vacuum chamber according to claim 6, wherein the first inductor coil is of a planar structure and provided on the bottom plate of the chamber body at the bottom of the electrostatic chuck.

8. The plasma vacuum chamber according to claim 7, wherein a gas inlet is also provided on the bottom plate of the chamber body, an external port of the gas inlet is connected to a corresponding gas supply line, and an internal port of the gas inlet is located inside the chamber body.

9. The plasma vacuum chamber according to claim 7, wherein an exhaust port is provided on the side wall of the chamber body at the bottom of the electrostatic chuck, the exhaust port being connected to a vacuumizing system.

10. The plasma vacuum chamber according to claim 6, wherein the source power supply is provided by a first radio frequency generator, and a first match circuit is connected between the first radio frequency generator and the first inductor coil.

11. The plasma vacuum chamber according to claim 1, wherein the electrostatic chuck is connected to a bias power supply.

12. The plasma vacuum chamber according to claim 11, wherein the bias power supply is provided by a second radio frequency generator, and a second match circuit is connected between the second radio frequency generator and the electrostatic chuck.

13. The plasma vacuum chamber according to claim 11, wherein structures connected to the electrostatic chuck further comprise: a chiller, a helium control system, and a chucking system.

14. The plasma vacuum chamber according to claim 9, wherein the vacuumizing system comprises a plurality of stages of vacuum pumps, valves, and vacuum lines.

15. The plasma vacuum chamber according to claim 2, wherein multiple lift pins are also provided in the electrostatic chuck.

16. The plasma vacuum chamber according to claim 1, wherein the chamber body is an etching chamber body.
